(19) United States
(12) Patent Application Publication
(10) Pub. No.: US 2026/0080142 A1
(43) Pub. Date: Mar. 19, 2026

(54) LAYOUT PLACEMENT METHOD, INTEGRATED CIRCUIT DESIGN METHOD INCLUDING THE SAME, AND INTEGRATED CIRCUIT DESIGN SYSTEM

(71) Applicant: Samsung Electronics Co., Ltd., Suwon-si (KR)

(72) Inventors: Jeongyoon Lee, Suwon-si (KR); Seunghwan Lee, Suwon-si (KR); Kyeongrok Jo, Suwon-si (KR); Youngwook Kim, Suwon-si (KR)

(21) Appl. No.: 19/256,019

(22) Filed: Jun. 30, 2025

(30) Foreign Application Priority Data
Sep. 19, 2024 (KR) 10-2024-0126719
Nov. 12, 2024 (KR) 10-20240160486

(51) Int. Cl. G06F 30/392; G06N 3/042

(52) U.S. Cl. CPC G06F 30/392; G06N 3/042

(57) ABSTRACT

An example method includes extracting a plurality of sub-cells based on netlist data; generating a first plurality of layout elements corresponding to the plurality of sub-cells; performing virtual placement of the first plurality of layout elements to obtain at least one virtually placed layout, the first plurality of layout elements corresponding to a plurality of layout elements that at least one template contains; selecting, based on evaluating the at least one virtually placed layout, a first template from the at least one template; and placing and routing the first plurality of layout elements based on the first template.

### CROSS-REFERENCE TO RELATED APPLICATIONS

This application claims priority under 35 U.S.C. § 119 to Korean Patent Application Nos. 10-2024-0126719, filed on Sep. 19, 2024, and 10-2024-0160486, filed on Nov. 12, 2024, in the Korean Intellectual Property Office, each of which is incorporated by reference herein in its entirety.

### BACKGROUND

Along with the gradual advancement of a semiconductor manufacturing process, design complexity has increased, and the time taken to design a layout has increased. Accordingly, the demand for automatic generation of a layout has increased. In addition, there exists a case where a target layout is generated under various boundary conditions in various memory devices.

Most layout placements of analog circuits are manually performed by a designing engineer. This is because analog constraints are considered and the preference of a layout may depend on each company, product, and engineer. The result of such a working scheme may significantly depend on the ability of an engineer and may be disadvantageous even in terms of time and efficiency. Therefore, a methodology, in which a layout is automatically generated, capable of satisfying various conditions while reflecting the preference of an existing layout is desired.

### SUMMARY

Some aspects of the present disclosure provide layout placement methods by which an optimal layout placement structure according to a varying boundary condition may be acquired.

Some aspects of the present disclosure provide methods of placing a layout. The method may include extracting a plurality of sub-cells based on netlist data; generating a first plurality of layout elements corresponding to the plurality of sub-cells; performing virtual placement of the first plurality of layout elements to obtain at least one virtually placed layout, the first plurality of layout elements corresponding to a plurality of layout elements that at least one template contains; selecting, based on evaluating the at least one virtually placed layout, a first template from the at least one template; and placing and routing the first plurality of layout elements based on the first template.

Some aspects of the present disclosure provide methods of designing an integrated circuit. The method may include a place and routing operation of generating layout data from netlist data, wherein the place and routing operation comprises: extracting a plurality of sub-cells from the netlist data, the netlist data including information characterizing a plurality of transistors; generating a first plurality of layout elements corresponding to the plurality of sub-cells, respectively; virtually placing the first plurality of layout elements based on template-related data to obtain a plurality of virtually placed layouts, wherein the template-related data comprises a second plurality of layout elements corresponding to the plurality of sub-cells, respectively; selecting, based on evaluating the plurality of virtually placed layouts, a template of which a wire length or area is minimized; and placing and routing the first plurality of layout elements based on the template.

Some aspects of the present disclosure provide systems for designing an integrated circuit. The system may include a processor; and a memory connected to the processor and storing instructions for layout placement to design the integrated circuit, wherein the processor is configured, when the instructions are executed, to extract a plurality of sub-cells based on netlist data; generate a first plurality of layout elements corresponding to the plurality of sub-cells; perform virtual placement of the first plurality of layout elements to obtain at least one virtually placed layout, the first plurality of layout elements corresponding to a plurality of layout elements that at least one template contains; select, based on evaluating the at least one virtually placed layout, an template; and place and route the first plurality of layout elements based on the template.

### BRIEF DESCRIPTION OF THE DRAWINGS

FIG. 1 is a flowchart of an example of a layout placement method.

FIG. 2 is a flowchart of an example of a method of generating a learning model.

FIG. 3 is an example flowchart illustrating correlation between the layout placement method of FIG. 1 and the method of FIG. 2.

FIGS. 4A, 4B, and 4C are diagrams illustrating examples of algorithms of generating a template by using relative position information.

FIG. 5 is a diagram illustrating virtual placement of an example layout based on the algorithms of FIGS. 4A, 4B, and 4C.

FIG. 6 is a diagram illustrating an example of a machine learning model for selecting an optimal template by learning templates.

FIGS. 7A and 7B are circuit diagrams illustrating examples of extraction of a plurality of sub-cells from netlist data.

FIG. 8 is a diagram illustrating examples of layout elements corresponding to a plurality of sub-cells.

FIG. 9 is a diagram illustrating an example of template data.

FIG. 10 is a diagram illustrating an example of a layout virtually placed according to a template.

FIG. 11 is a diagram illustrating an example of a method of evaluating a virtually placed layout.

FIG. 12 is a flowchart illustrating an example of a method of fabricating an integrated circuit.

FIG. 13 is a block diagram illustrating an example of a computing system for designing an integrated circuit.

### DETAILED DESCRIPTION

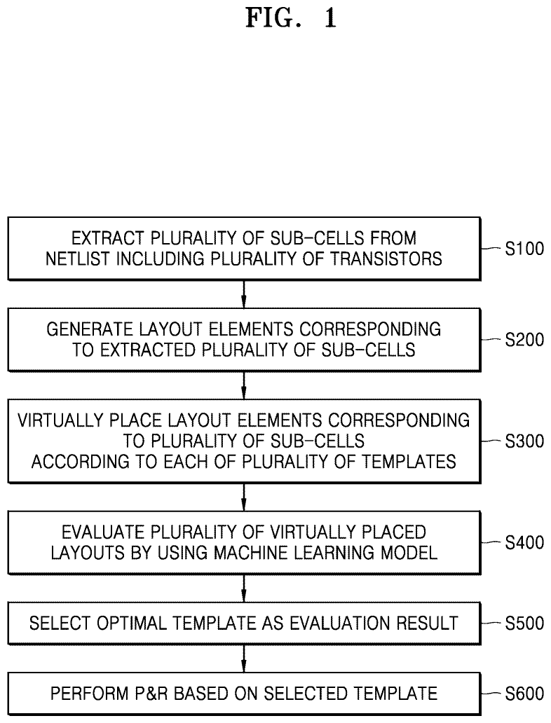

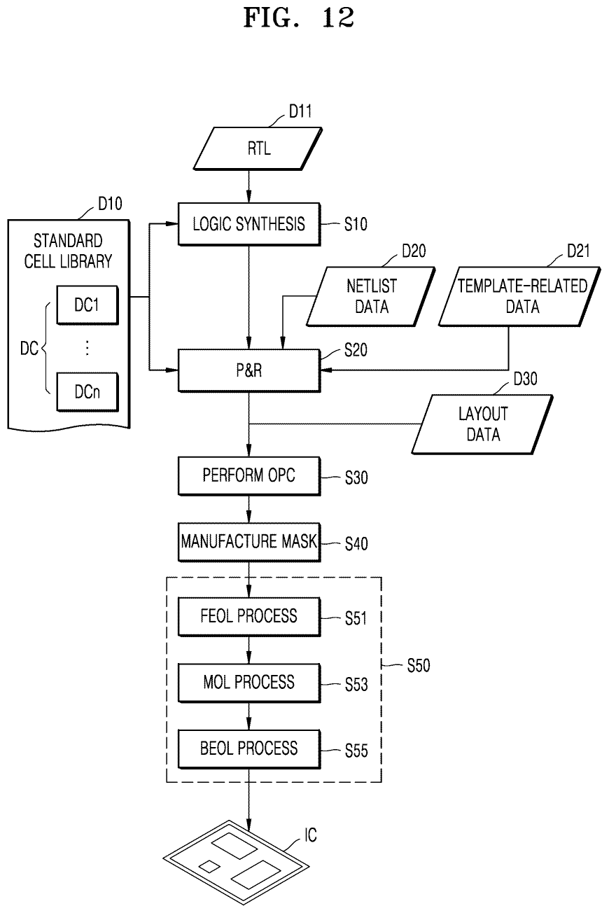

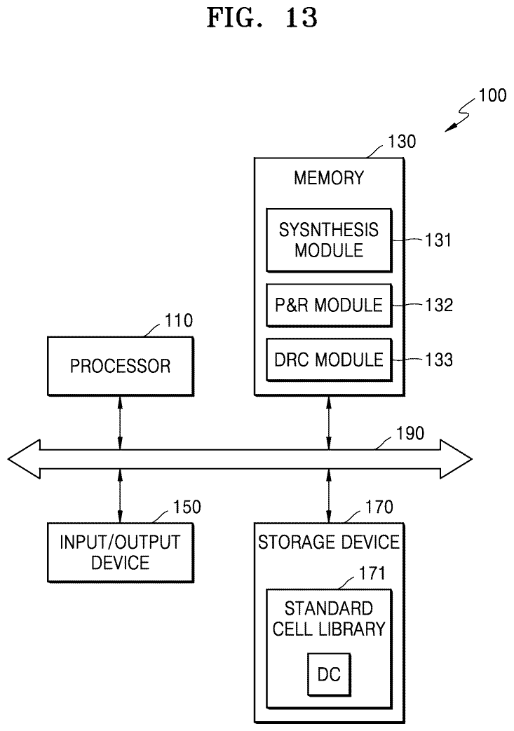

FIG. 1 is a flowchart of an example of a layout placement method. The layout placement method may be applied to a layout placement operation in a method of fabricating an integrated circuit (IC). Examples of a method of fabricating an IC and a system therefor are described below in detail with reference to FIGS. 12 and 13.

According to the layout placement method, information on sub-cells may be extracted from netlist data including a plurality of transistors, layout elements corresponding to the sub-cells may be virtually placed according to a corresponding template, and a virtually placed layout may be evaluated through a machine learning model, thereby selecting a template having an optimal condition from among a plurality of templates. In addition, place and routing (P&R) may be performed based on the selected template. In some implementations, P&R is not substantially performed for all the templates but performed only for a template corresponding to a selected optimal layout, and thus, even for layouts having a new boundary condition, a layout of which the area and the wire length (WL) are minimized may be selected.

Hereinafter, an example of a particular layout placement method is described.

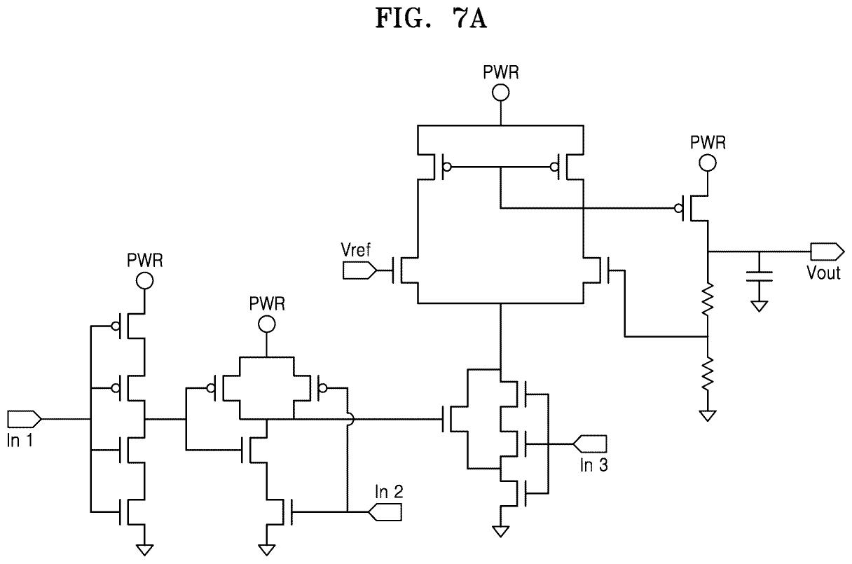

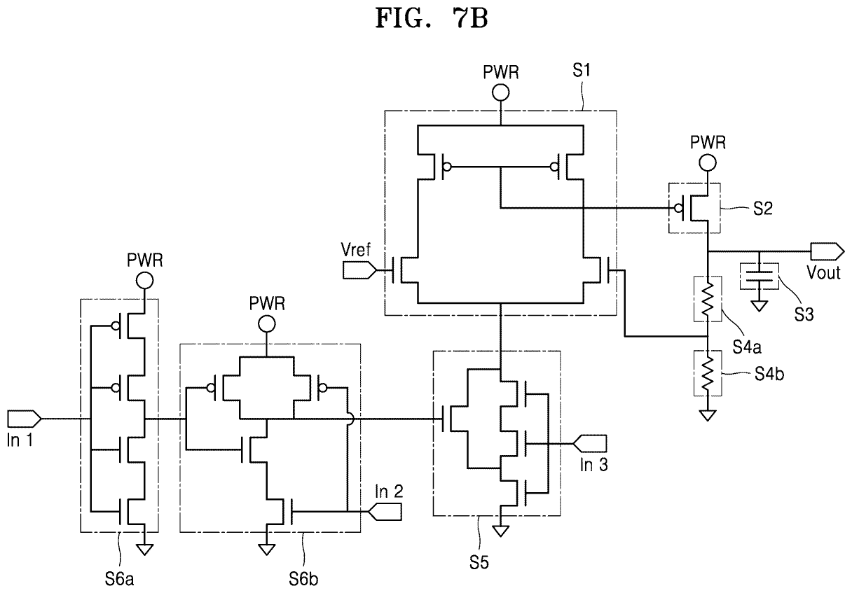

Referring to operation S100, a plurality of sub-cells may be extracted from netlist data including a plurality of transistors. The netlist data may be a file in which (i) the types and sizes of devices used in a circuit diagram drawn to perform simulation or layout after finishing a circuit design, (ii) connection states between the devices, and the like are extracted and recorded. Netlist data may comprise information characterizing a plurality of transistors or other circuit components, such as connection structure, component type, size, etc. The extraction of the plurality of sub-cells may be a task for classifying the plurality of transistors included in the netlist data according to a certain criterion. In some implementations, the extraction of the plurality of sub-cells may be a task for classifying cells having certain functions by combining the plurality of transistors included in the netlist data. In some implementations, a sub-cell may indicate a minimum-unit device configured to perform a certain function by combining a plurality of transistors or other circuit elements. This is more particularly described with reference to FIGS. 7A and 7B.

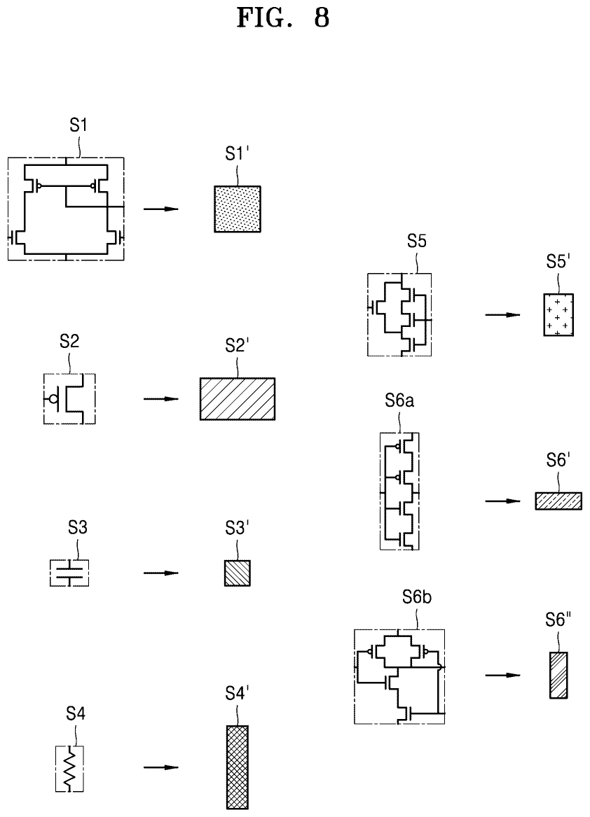

Referring to operation S200, layout elements corresponding to the extracted plurality of sub-cells may be generated. In some implementations, each of the plurality of sub-cells may correspond to one layout element. In some implementations, each of the plurality of sub-cells may be categorized according to a criterion set by a user. In some implementations, a layout element corresponding to each sub-cell may exist, and even though sub-cells belong to the same category, if the sub-cells have different transistor configurations, the shapes of layout elements corresponding to the sub-cells may differ from each other. In some implementations, the sizes, shapes, and the like of layout elements corresponding to a plurality of sub-cells included in any one product may be pre-defined in a design stage. In some implementations, layout elements corresponding to a plurality of sub-cells included in any one product may have different sizes and shapes. A particular example of a plurality of sub-cells and categories is described below with reference to FIG. 8.

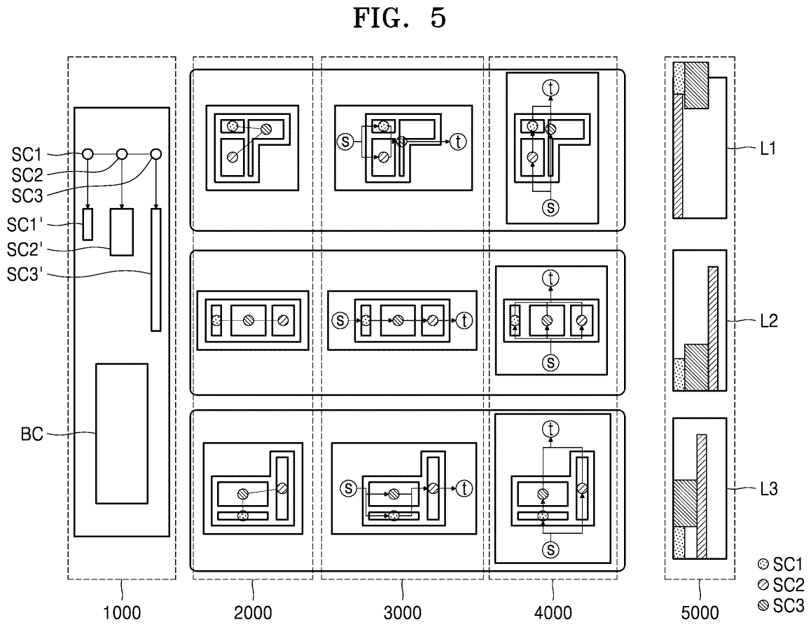

Referring to operation S300, layout elements corresponding to the plurality of sub-cells may be virtually placed according to each of a plurality of templates. In some implementations, the layout elements corresponding to the plurality of sub-cells may be placed according to a template including the layout elements. In this case, the virtual placement may be performed by considering a relative position relationship among the layout elements included in the template, and the virtual placement may be performed in a category unit including the plurality of sub-cells. The virtual placement is described below in more detail with reference to FIG. 5.

In some implementations, the virtual placement in operation S300 may be performed by any one of various placements of a layout placement operation. In some implementations, the virtual placement in operation S300 may be performed by any one of global placement, legalization, detailed placement, but the present disclosure is not limited thereto, and the virtual placement may be performed in an operation defined by the user.

Referring to operation S400, a plurality of virtually placed layouts may be evaluated using a machine learning model. In some implementations, based on a machine learning model generated by learning a plurality of templates, a virtually placed layout generated in operation S300 may be input to the machine learning model, and a result value about the WL or area of the virtually placed layout may be output as an output responding to the input. By inputting the plurality of virtually placed layouts generated in operation S300 to the machine learning model, evaluation parameters for the plurality of virtually placed layouts may be output and compared with each other.

Referring to operation S500, an optimal template may be selected as a result of the evaluation. WL or area values respectively corresponding to the plurality of virtually placed layouts may be acquired by inputting the plurality of virtually placed layouts to the machine learning model in operation S400, and a template corresponding to a virtually placed layout having the minimum WL or area value may be selected by comparing the acquired WL or area values with each other.

Referring to operation S600, actual P&R may be performed based on the selected template. According to the present disclosure, a template corresponding to a layout in which the plurality of sub-cells are placed to have an optimal condition may be selected through the machine learning model, thereby performing actual P&R. According to the present disclosure, instead of performing, for all templates, routing requiring substantially a long time, P&R may be performed according to a layout corresponding to a finally selected template, and thus, the present disclosure may be efficient in terms of time.

Along with the advancement of a process, the time taken for a layout has gradually increased, and a method of automatically generating a layout is required. The present disclosure proposes an automatic layout generation methodology capable of minimizing an area and a WL while maintaining the preference of an existing productized layout elements. According to the present disclosure, the placement of productized layout elements may be templatized, and a layout may be generated while maintaining an existing placement template even under various boundary conditions by using the templatized placement.

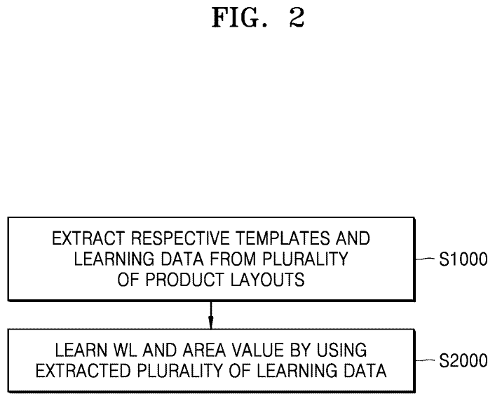

FIG. 2 is a flowchart of an example of a method of generating a learning model.

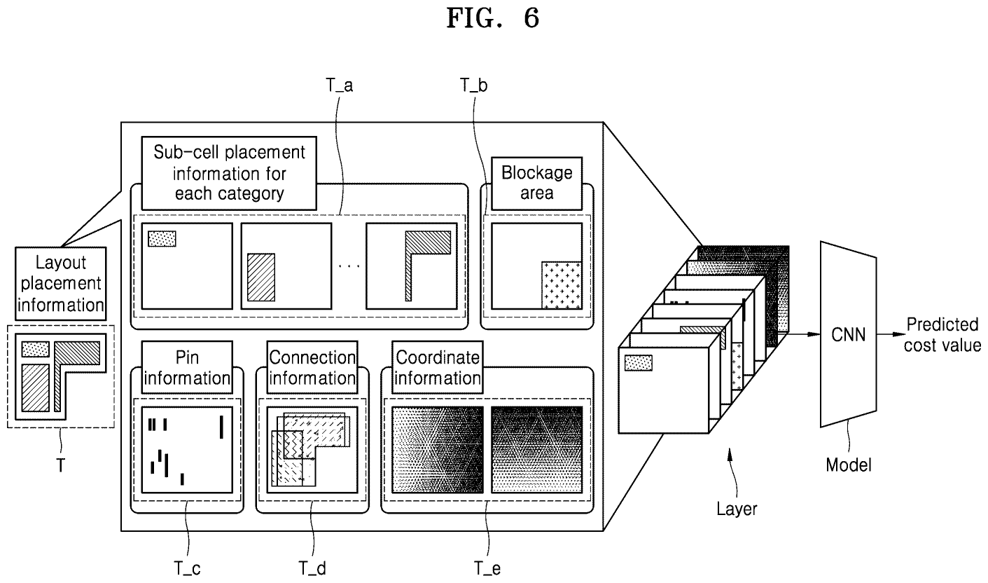

Referring to operation S1000, a plurality of templates and learning data may be extracted from a plurality of product layouts, respectively. In the present disclosure, a template may indicate data including a layout placement structure of sub-cells included in an IC productized or to be productized or a placement structure of categories corresponding to the sub-cells and information on a boundary condition under which a layout is placed. In some implementations, the template may be data about a layout placement which is stored in a database, and of which the verification is completed. In some implementations, the template may be data about a layout placement structure and a boundary condition of sub-cells of an IC actually used or to be possibly used. The template may be data obtained by extracting placement information of mask tape out (MTO) products. In the present disclosure, a product layout may indicate a layout placement structure of layout elements corresponding to MTO products. In the present disclosure, learning data may indicate data to be used for machine learning among layout elements included in a template. In some implementations, the learning data may include layout elements included in a template, boundary information, pin information, and the like. The learning data is described below in more detail with reference to FIG. 6.

Referring to operation S2000, WL and area values may be learned using the extracted plurality of learning data. In some implementations, the plurality of templates may be learned through an artificial intelligence (AI) learning model. In some implementations, the AI learning model may be machine learning including deep learning or rule-based AI. The deep learning may use an artificial neural network model. In addition, the deep learning may use a convolutional neural network (CNN) model. the AI learning model is described below in detail with reference to FIG. 6. In the present disclosure, a model for learning a plurality of templates is commonly referred to as a machine learning model.

Through operations S1000 and S2000, a template including information on a layout placement structure corresponding to a plurality of products and learning data for learning the template may be extracted, and a machine learning model capable of outputting WL and area values by performing machine learning based on the template and the learning data may be generated.

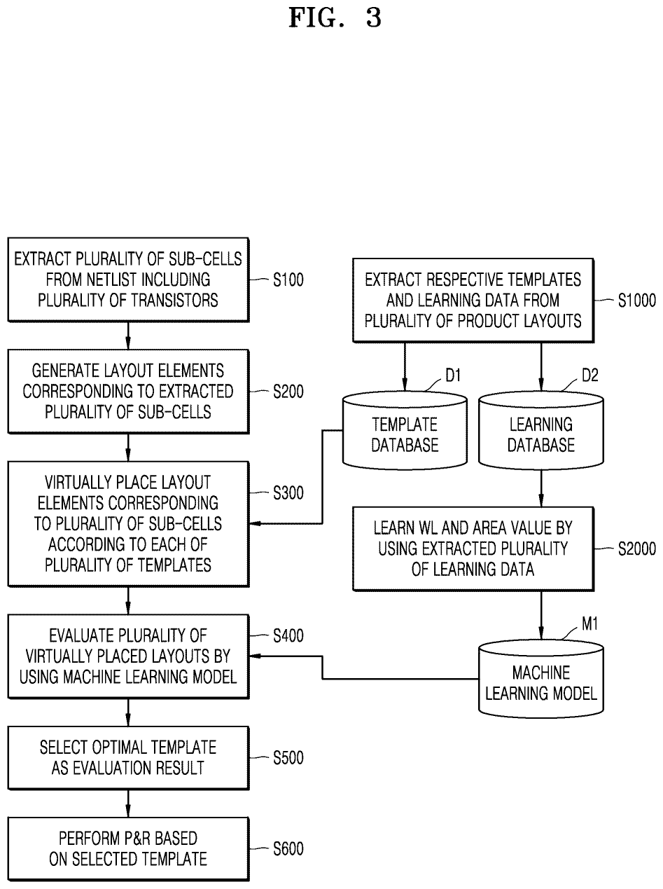

In some implementations, the method shown in FIG. 2 may be independent to the layout placement method shown in FIG. 1. However, the layout placement method shown in FIG. 1 may be performed based on data generated in a process of performing the method shown in FIG. 2. The relationship between the layout placement method shown in FIG. 1 and the method shown in FIG. 2 is described in more detail with reference to FIG. 3.

FIG. 3 is an example flowchart illustrating the correlation between the layout placement method of FIG. 1 and the method of FIG. 2.

Referring to FIG. 3, operations S100, S200, S300, S400, S500, and S600 of the layout placement method of FIG. 1 and operations S1000 and S2000 of the method of FIG. 2 are provided. The description of operations S100, S200, S300, S400, S500, and S600 and operations S1000 and S2000 is the same as made above with reference to FIGS. 1 and 2 and is thus not repeated.

Referring to FIG. 3, a template database D1 and a learning database D2 output in operation S1000 are provided. In some implementations, templates including placement-related information of layout elements corresponding to a plurality of product layouts may be stored in the template database D1. In some implementations, learning data respectively corresponding to the templates may be included in the learning database D2. In some implementations, the learning database D2 may include information for learning a template, for example, pieces of information, such as boundary information of the template, position information of layout elements included in the template, and connection-related information. In some implementations, the learning database D2 may also include information on a WL and an area corresponding to each template. In some implementations, the template database D1 and the learning database D2 may be databases in which pieces of information extracted in operation S1000 are stored.

Referring to FIG. 3, in operation S2000, a plurality of templates may be learned based on the pieces of information stored in the learning database D2. Accordingly, a machine learning model M1 may be generated. The machine learning model M1 may be a model configured to output, as an output value, the WL value and/or the area value of a corresponding template when learning data included in the corresponding template is input as an input value.

Operation S300 of FIG. 3 may include virtually placing a layout corresponding to a plurality of sub-cells according to each of a plurality of templates. In some implementations, the plurality of templates used in operation S300 may be included in the template database D1. In operation S300, templates including the same layout elements corresponding to the plurality of sub-cells may be selected from the template database D1, and virtual placement may be performed according to the selected templates.

Operation S400 of FIG. 3 may include evaluating a plurality of virtually placed layouts through a machine learning model. In some implementations, the machine learning model used in operation S400 may be the machine learning model M1 generated in operation S2000. That is, based on a machine learning model trained according to information stored in a plurality of product layouts, the plurality of virtually placed layouts may be input to the machine learning model, and a WL value or an area value corresponding to each virtually placed layout may be extracted.

Through acquiring a layout placement structure by using the method shown in FIG. 3, an appropriate layout placement structure according to a varying boundary condition may be easily acquired. In addition, according to the present disclosure, because a layout is generated based on a template including information on a productized layout, placement knowhow included in an existing product may be used. Hereinafter, the layout placement method according to the present disclosure is described in more detail.

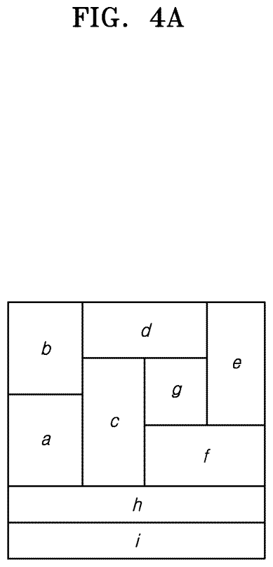

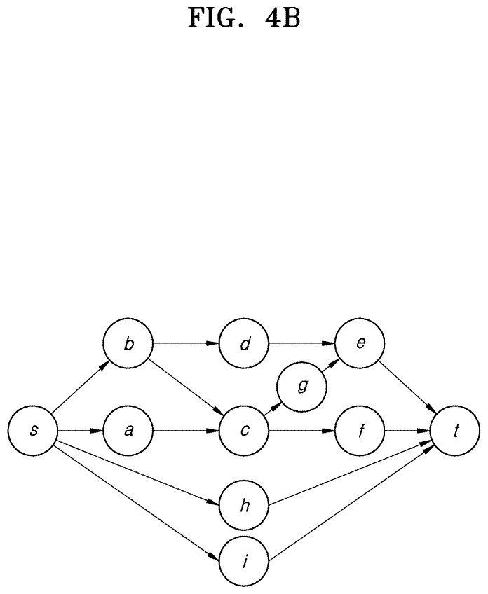

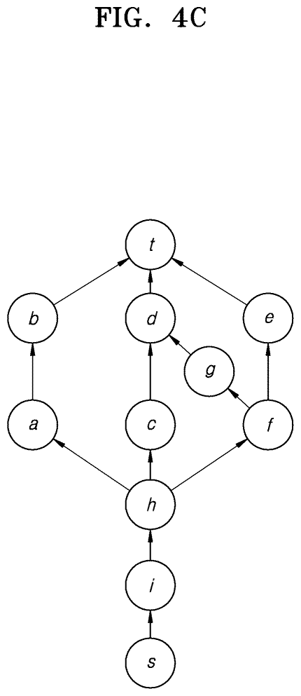

FIGS. 4A, 4b, and 4C are diagrams illustrating examples of algorithms of generating a template by using relative position information.

FIG. 4A illustrates a configuration of categories which may be placed in a layout, the categories being represented by different alphabets and relatively placed. In some implementations, to calculate an area or a total WL on a floor plan, the necessity of abstracting data may be required. Results of abstracting data based on different algorithms may be shown in FIGS. 4B and 4C. Referring to FIGS. 4B and 4C, relative placement relationships of categories which may be placed in a layout are represented by directive graphs.

FIG. 4B may be an example in which a connection relationship among elements is output using a horizontal constraint graph (HCG). FIG. 4C may be an example in which a connection relationship among elements is output using a vertical constraint graph (VCG).

In both implementations of FIGS. 4B and 4C, a sequence may be indicated by assigning a sink node (a t node) and a source node (an s node). In some implementations, the source node may be a departure node, and the sink node may be a destination node.

In some implementations, the implementation of FIG. 4B may be a scheme in which a weight is added to each node and the weight-added nodes are stored, and in this case, the weight may indicate the width of a corresponding block. In the implementation of FIG. 4B, the placement position of each node may be abstracted by adding a weight to the width of a block.

In some implementations, the implementation of FIG. 4C may be a scheme in which a weight is added to each node and weight-added nodes are stored, and in this case, the weight may indicate the height of a corresponding block. In the implementation of FIG. 4C, the placement position of each node may be abstracted by adding a weight to the height of a block.

Based on such an algorithm, a graph indicating the relative position of each block may be abstracted, and a layout may be generated by reflecting the graph. Based on such an algorithm, a data amount may be reduced, and only the position of a category in which a sub-cell is included may be represented. This is only illustrative, and in addition to the HCG and the VCG, various relative position representing algorithms according to the present disclosure may be applied. In some implementations, a meta grid scheme may be used as an algorithm of representing relative positions. In some implementations, the meta grid scheme may be a concept which commonly calls algorithms of representing relative positions among elements. In some implementations, for the algorithms of representing relative positions, alphabet may be used. Hereinafter, for convenience of description, a method of generating a template by using the VCG and the HCG is shown.

FIG. 5 is a diagram illustrating virtual placement of an example layout based on the algorithms of FIGS. 4A, 4B, and 4C.

Referring to FIG. 5, a plurality of sub-cells SC1, SC2, and SC3 and layout elements SC1′, SC2′, and SC3′ respectively corresponding to the plurality of sub-cells SC1, SC2, and SC3 are provided. In addition, a boundary condition BC of a layout in which the layout elements SC1′, SC2′, and SC3′ respectively corresponding to the plurality of sub-cells SC1, SC2, and SC3 are to be placed may be provided in an element 1000. In some implementations, the element 1000 of FIG. 5 may correspond to operations S100 and S200 of FIG. 1. In some implementations, the plurality of sub-cells SC1, SC2, and SC3 may be sub-cells extracted from a netlist based on stored data in operation S100 of FIG. 1. In some implementations, the layout elements SC1′, SC2′, and SC3′ respectively corresponding to the plurality of sub-cells SC1, SC2, and SC3 may be a result of generating layout elements respectively corresponding to the plurality of sub-cells SC1, SC2, and SC3 in operation S200 of FIG. 1. In some implementations, in the present disclosure, the layout elements SC1′, SC2′, and SC3′ are placed according to the boundary condition BC, and in this process, a placement structure of the layout elements SC1′, SC2′, and SC3′, having the most optimal condition, for example, having the minimized WL and/or area, is obtained based on a template. In some implementations, the boundary condition BC may indicate a condition for a boundary corresponding to an IC to be designed.

As shown in FIG. 5, the shapes and sizes of the layout elements SC1′, SC2′, and SC3′ respectively corresponding to the plurality of sub-cells SC1, SC2, and SC3 may be previously determined based on information on an IC to be designed.

Referring to an element 2000 of FIG. 5, some of templates stored in the template database D1 of FIG. 3 are provided. In some implementations, based on various templates including the plurality of sub-cells SC1, SC2, and SC3, the layout elements SC1′, SC2′, and SC3′ respectively corresponding to the plurality of sub-cells SC1, SC2, and SC3 may be placed under the boundary condition BC corresponding to an IC to be designed.

In the templates of the element 2000, layout elements of categories corresponding to the plurality of sub-cells SC1, SC2, and SC3 are provided under the plurality of sub-cells SC1, SC2, and SC3, respectively. Referring to the templates in the element 2000, each of the templates includes layout elements of categories corresponding to the plurality of sub-cells SC1, SC2, and SC3, respectively, but the sizes and the placement positions of the layout elements of the categories respectively corresponding to the plurality of sub-cells SC1, SC2, and SC3 and boundary conditions are different from each other in the templates. That is, because the templates respectively relate to layouts applied to different products, a boundary condition and the area and placement positions of layout elements in each template may vary.

In some implementations, each category included in a template may include one or more sub-cells, and sub-cells included in the same category may have a common criterion defined by a user. That is, because three layout elements respectively corresponding to three sub-cells SC1, SC2, and SC3 in each template shown in the element 2000 are provided, the three sub-cells SC1, SC2, and SC3 may not be included in the same category.

Referring to the templates in the element 2000, the layout elements SC1′, SC2′, and SC3′ respectively corresponding to the plurality of sub-cells SC1, SC2, and SC3 extracted based on netlist data may be the same as layout elements included in each template. That is, the layout elements SC1′, SC2′, and SC3′ respectively corresponding to the plurality of sub-cells SC1, SC2, and SC3 may be placed based on the templates in the element 2000, which include the same layout elements.

Referring to elements 3000 and 4000, the position relationship among categories corresponding to the layout elements stored in each of the templates of the element 2000 may be extracted by an HCG and a VCG. In some implementations, a criterion of determining relative positions by the HCG and the VCG may be applied for each category. In some implementations, when two sub-cells among the three sub-cells shown in FIG. 5 are included in a first category and the remaining one sub-cell is included in a second category, the relative positions of the first category and the second category may be determined.

As described above, by considering templates according to the elements 2000, 3000, and 4000 and relative position information of categories corresponding to layout elements in the templates, virtually placed layouts L1, L2, and L3 may be generated. An element 5000 may correspond to operation S300 of FIG. 1.

Referring to FIG. 5, based on various templates including the plurality of sub-cells SC1, SC2, and SC3, a graph may be generated by considering a relative position relationship in a corresponding template, and then the layout elements SC1′, SC2′, and SC3′ may be placed according to the boundary condition BC to be generated according to the graph, thereby finally generating the virtually placed layouts L1, L2, and L3.

In some implementations, in the virtually placed layout L1, because layout elements are placed out of the boundary condition BC as a result of considering relative position information, the virtually placed layout L1 may not be included in layouts to be evaluated by being input to a machine learning model.

As described with reference to FIG. 5, a plurality of sub-cells may be extracted from netlist data, and layout elements respectively corresponding to the plurality of sub-cells may be virtually placed according to the boundary condition BC based on templates including layout elements (or categories) respectively corresponding to the plurality of sub-cells. According to the present disclosure, when layout elements are placed under a boundary condition different from a layout included in a template, the layout elements may be flexibly placed using a template including layout elements (or categories) respectively corresponding to a plurality of sub-cells. This method may be more efficient than a comparative example because this method is automatically performed based on information on a plurality of sub-cells and a template instead of being manually performed by an engineer.

Although FIG. 5 shows examples (the elements 3000 and 4000) of abstracting a connection relationship of layout elements included in a template based on relative position information of the layout elements included in a template, the template may be reconfigured to include intents of a designer. In some implementations, a template may be generated according to various conditions, such as layout placement information of a corresponding product, layout preference information, and intents of a designer.

FIG. 6 is a diagram illustrating an example of a machine learning model for selecting an optimal template by learning templates.

Referring to FIG. 6, an example of the machine learning model configured to predict a WL is shown. In some implementations, learning data T_a, T_b, T_c, T_d, and T_e included in the learning database D2 shown in FIG. 3 may be input to the machine learning model.

For convenience of description, FIG. 6 shows that one first template T is input. The first template T may indicate layout placement information. When the first template T is input, pieces of information used as an input may include placement information T_a of a sub-cell for each category in which each of sub-cells included in the first template T is included, information T_b on an area in which the sub-cells are not placed (information on a constraint area or information on a boundary condition), information T_c on connected pins, information T_d on a connection structure of the sub-cells (or categories), and coordinate information T_e. The placement information T_a of a sub-cell for each category in which each of sub-cells is included may be placement position information, size information, and area information of each of the sub-cells. The information T_b on an area in which the sub-cells are not placed (information on a constraint area) may indicate an area in which the sub-cells cannot be placed to determine the boundary condition. The information T_c on connected pins may indicate the placement positions of pins for electrically connecting each of the sub-cells, the number of pins, and the like. The information T_d on a connection structure of the sub-cells may be contact information for connecting the sub-cells in terms of metal layer. The coordinate information T_e may indicate coordinate information of an area in which a layout is placed.

The input pieces of information may be generated as a two-dimensional array, wherein the input pieces of information form respective layers. The pieces of information may be input to the machine learning model, and a machine learning model Model may be trained to output a WL value or an area value of a template corresponding to the input pieces of information. The machine learning model Model according to an implementation may be a CNN model but is not limited thereto.

The machine learning model Model shown in FIG. 6 may be trained based on learning data included in the learning database D2 of FIG. 3. The machine learning model Model according to an implementation may be trained using learning input data of a plurality of templates and WL/area values corresponding to the plurality of templates. WL values and area values respectively corresponding to the virtually placed layouts L2 and L3 generated with reference to FIG. 5 may be output by inputting the virtually placed layouts L2 and L3 to the machine learning model Model which is completely trained, and a template having the minimum WL value and/or area value may be selected by comparing the output values. Finally, sub-cells may be placed according to the selected template.

Hereinafter, the layout placement method is described based on more particular examples.

FIGS. 7A and 7B are circuit diagrams illustrating examples of extraction of a plurality of sub-cells from netlist data, according to an implementation.

FIG. 7A shows an example of netlist data. The netlist data shown in FIG. 7A may include a plurality of transistors and other circuit elements, such as a resistor and a capacitor. In some implementations, the netlist data may be created on a transistor level. In some implementations, the netlist data may be data related to a mixed-signal circuit including a digital logic circuit and an analog logic circuit.

In some implementations, the netlist data of FIG. 7A may be related to a low dropout (LDO) regulator circuit. According to the netlist data shown in FIG. 7A, a plurality of transistors may be mixed such that a function performed by each transistor is not clearly indicated. One example in which a plurality of sub-cells are extracted from the netlist data shown in FIG. 7A is shown in FIG. 7B.

Referring to FIG. 7B, a first sub-cell S1, a second sub-cell S2, a third sub-cell S3, fourth sub-cells S4a and S4b, a fifth sub-cell S5, and sixth sub-cells S6a and S6b extracted from the netlist data shown in FIG. 7A are provided.

In some implementations, the first sub-cell S1 may be a differential amplifier circuit. The second sub-cell S2 may be a pass transistor. The third sub-cell S3 may be a capacitor. The fourth sub-cells S4a and S4b may be resistors. The fifth sub-cell S5 may be a transistor array. The sixth sub-cells S6a and S6b may be digital logic gates.

In some implementations, each sub-cell may be a unit of a circuit device configured to perform a different function. In some implementations, the first sub-cell S1, the second sub-cell S2, the third sub-cell S3, the fourth sub-cells S4a and S4b, the fifth sub-cell S5, and the sixth sub-cells S6a and S6b extracted in FIG. 7B may correspond to respective categories. For example, the first sub-cell S1 may correspond to a first category, the second sub-cell S2 may correspond to a second category, the third sub-cell S3 may correspond to a third category, the fourth sub-cells S4a and S4b may correspond to a fourth category, the fifth sub-cell S5 may correspond to a fifth category, and the sixth sub-cells S6a and S6b may correspond to a sixth category. Each category may be a higher concept including corresponding sub-cells. In some implementations, the sixth category may be a category including digital logic devices. In some implementations, the sixth category may be a category including sub-cells including digital logic devices, such as an AND gate, a NAND gate, and an OR gate, but is not limited thereto. The configuration of a category may be changed by a user according to a criterion of a user.

The netlist data shown in FIGS. 7A and 7B may be one example, and a plurality of sub-cells may be extracted based on netlist data including a much more number of transistors and other circuit elements than those shown in FIGS. 7A and 7B.

FIG. 8 is a diagram illustrating examples of layout elements corresponding to a plurality of sub-cells, according to an implementation.

Referring to FIG. 8, layout elements S1′, S2′, S3′, S4′, S5′, S6′, and S6″ respectively corresponding to a plurality of sub-cells S1, S2, S3, S4, S5, S6a, and S6b extracted in FIG. 7B are provided. Referring to FIG. 8, the layout elements S1′, S2′, S3′, S4′, S5′, S6′, and S6″ may have previously determined sizes and shapes to respectively correspond to the plurality of sub-cells S1, S2, S3, S4, S5, S6a, and S6b.

As shown in FIG. 8, when respective elements of the sub-cells S6a and S6b included in the same category are different from each other, even though the elements are included in the same category, different layout elements S6′ and S6″ may be generated based on the sub-cells S6a and S6b.

According to the present disclosure, a category included in a template or netlist data may include one or more sub-cells, and sub-cells included in the same category may have a common criterion defined by a user. Even though a plurality of sub-cells are included in one category, if the configuration of transistors included in each of the plurality of sub-cells is different, layout elements corresponding to the plurality of sub-cells may be provided to have different shapes and sizes.

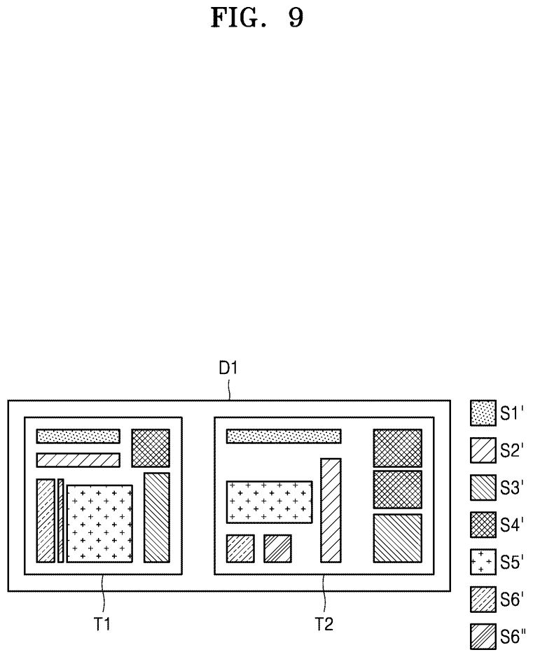

FIG. 9 is a diagram illustrating an example of template data.

Referring to FIG. 9, first template data T1 and second template data T2 included in a template database D1 are provided. This is for convenience of description, and the number of template data actually included in the template database D1 may be greater than the number shown in FIG. 9.

In the present disclosure, a size in template data or a layout may indicate a boundary condition in the template data or the layout. The sizes of the first template data T1 and the second template data T2 shown in FIG. 9 may be different from each other. A size may depend on a boundary condition of an IC corresponding to each template data. In some implementations, virtual placement may be performed based on template data including all of a plurality of sub-cells S1, S2, S3, S4, S5, S6a, and S6b extracted from netlist data.

Referring to the first template data T1, a layout placement structure including a first layout element S1′, a second layout element S2′, a third layout element S3′, a fourth layout element S4′, a fifth layout element S5′, and sixth layout elements S6′ and S6″ is provided.

Referring to the second template data T2, a layout placement structure including the first layout element S1′, the second layout element S2′, the third layout element S3′, the fourth layout element S4′, the fifth layout element S5′, and the sixth layout elements S6′ and S6″ is provided.

Referring to the first template data T1 and the second template data T2, each of the first template data T1 and the second template data T2 includes the first layout element S1′, the second layout element S2′, the third layout element S3′, the fourth layout element S4′, the fifth layout element S5′, and the sixth layout elements S6′ and S6″, but the first template data T1 differs from the second template data T2 in that the second template data T2 additionally includes one fourth layout element S4′.

As described above, even when all layout elements are included but differ in number, the layout elements may be used as template data.

The template data selection criteria described in the present disclosure are not limited to those shown in FIG. 9, and template data may be selected based on other different criteria. In some implementations, when the number of template data including all layout elements corresponding to a plurality of sub-cells extracted from netlist data is greater than a determined reference value, only template data having the same number of layout elements except for template data having different numbers of layout elements may be selected and used for virtual placement. In some implementations, when the number of template data including all layout elements corresponding to a plurality of sub-cells extracted from netlist data is less than the determined reference value, template data having a less number of layout elements may also be selected and used for virtual placement.

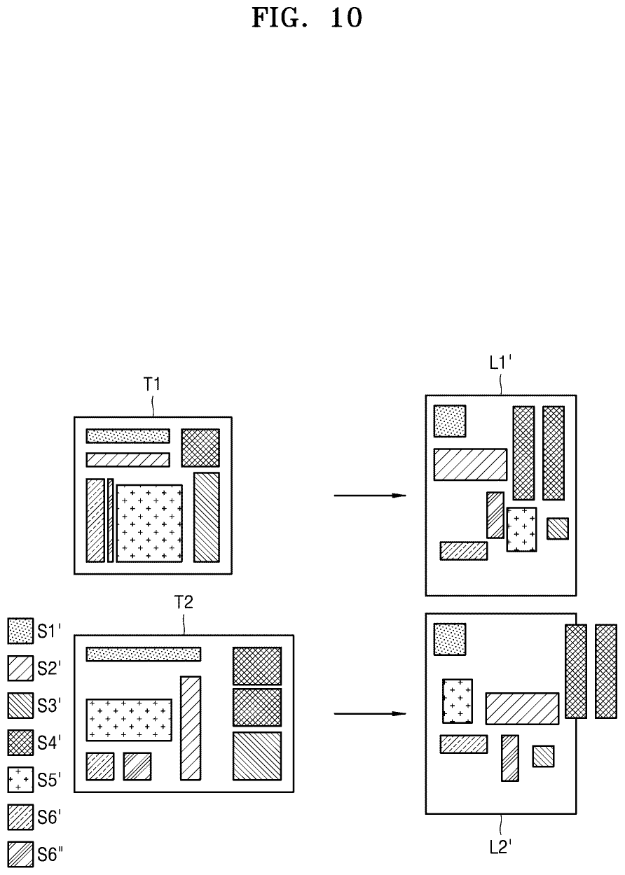

FIG. 10 is a diagram illustrating an example of a layout virtually placed according to a template.

In some implementations, FIG. 10 shows a first layout L1′ obtained by virtually placing the layout elements shown in FIG. 8 according to a boundary condition based on the first template data T1 of FIG. 9 and a second layout L2′ obtained by virtually placing the layout elements shown in FIG. 8 according to the boundary condition based on the second template data T2 of FIG. 9. The boundary condition of the first layout L1′ and the second layout L2′ in FIG. 10 may be determined in advance in a design stage. The boundary condition of the first layout L1′ and the second layout L2′ in FIG. 10 may be a boundary condition in an IC to be designed.

The first layout L1′ and the second layout L2′ may be result layouts in which layout elements corresponding to the sub-cells of FIG. 7B are virtually placed according to the boundary condition. In some implementations, because the number of fourth sub-cells S4a and S4b shown in FIG. 7B is 2 and the fourth sub-cells S4a and S4b are included in the fourth category, the fourth sub-cells S4a and S4b are shown as two fourth layout elements S4′. Because the sixth sub-cells S6a and S6b are included in the sixth category but have different configurations, the sixth sub-cells S6a and S6b are shown as sixth layout elements S6′ and S6″ different from each other, respectively. In some implementations, the same layout elements corresponding to a plurality of sub-cells included in the same category may be shown as a layout element corresponding to one category and placed in a layout. Referring to FIG. 7B, the two fourth sub-cells S4a and S4b may be shown as one fourth layout element. That is, a plurality of sub-cells corresponding to the same layout elements included in the same category may be placed as one layout element in terms of the category or placed as a plurality of layout elements in terms of the plurality of sub-cells when the plurality of sub-cells are placed in a layout.

Referring to FIG. 10, the first layout L1′ may be formed by reflecting the relative position relationship of the layout elements included in the first template data T1. Referring to the first template data T1, a second layout element S2′ is placed under a first layout element S1′, a fourth layout element S4′ is placed to the right of the first layout element S1′ and the second layout element S2′, and the sixth layout elements S6′ and S6″, a fifth layout element S5′, and a third layout element S3′ are placed under the second layout element S2′ and the fourth layout element S4′. The fifth layout element S5′ is placed to the right of the sixth layout elements S6′ and S6″, and the third layout element S3′ is placed to the right of the fifth layout element S5′.

Referring to the first layout L1′, the first layout element S1′ to the sixth layout elements S6′ and S6″ may be virtually placed by reflecting the relative position relationship of the layout elements included in the first template data T1.

Referring to FIG. 10, the second layout L2′ may be formed by reflecting the relative position of the layout elements included in the second template data T2. Referring to the second template data T2, the fourth layout element S4′ is placed to the right of the first layout element S1′, the fifth layout element S5′ and the second layout element S2′ are placed under the first layout element S1′, the sixth layout elements S6′ and S6″ are placed under the fifth layout element S5′, and the third layout element S3′ is placed under the fourth layout element S4′.

Referring to the second layout L2′, the first layout element S1′ to the sixth layout elements S6′ and S6″ may be virtually placed by reflecting the relative position relationship of the layout elements included in the second template data T2.

In some implementations, in a process of generating the first layout L1′ and the second layout L2′ by performing virtual placement, relative placement relationship algorithms among categories, as shown in FIGS. 4A to 4C, may be used. In this case, a relative placement relationship may be applied for each category, a plurality of sub-cells included in the same category may be placed to correspond to a position where a corresponding category is placed, and the placement positions of the plurality of sub-cells may be changed in the position where the corresponding category is placed.

Referring to the second layout L2′, as a result of performing virtual placement to correspond to the relative position relationship of the second template data T2, some layout elements may be placed outside a boundary condition. Therefore, in this case, the second template data T2 may not be suitable for reference template data to place the layout elements of FIG. 8 according to the boundary condition, and the second layout L2′ virtually placed according to the second template data T2 may also be unsuitable data.

That is, when virtually placed layouts are generated based on a plurality of templates, a layout not satisfying a boundary condition may not be a layout on which machine learning is to be performed. A layout not satisfying a boundary condition may indicate a layout in which a layout element outside the boundary condition exists as a result of virtually placing all layout elements, like the second layout L2′.

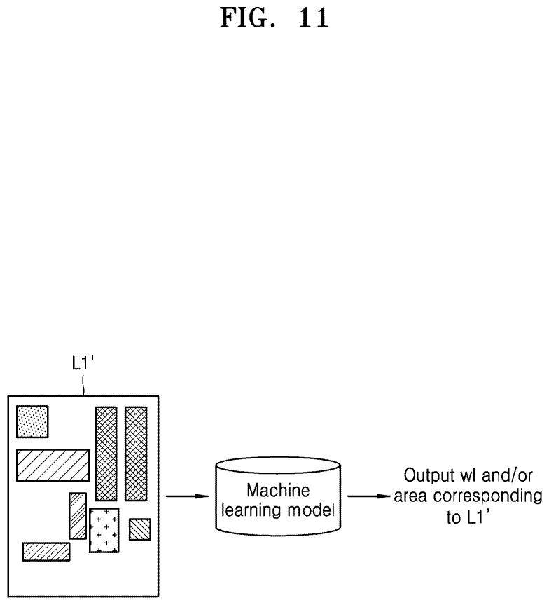

FIG. 11 is a diagram illustrating an example of a method of evaluating a virtually placed layout.

Referring to the results of FIG. 10, the first layout L1′ satisfying the boundary condition may be input to a machine learning model, and a WL value and/or an area value corresponding to the first layout L1′ may be output. By repeating the process of FIG. 10, a plurality of virtually placed layouts may be generated and input to the machine learning model, and then result values of the plurality of virtually placed layouts may be compared to select a layout satisfying a minimum WL and area condition.

A template corresponding to the selected layout may be selected, and the selected template may be a template in which an area in which a plurality of layout elements are placed and a WL are minimized.

Based on the processes of FIGS. 7A to 11, a layout may be placed. According to the present disclosure, based on template data including information on existing layout placement, virtual placement may be performed to generate virtually placed layouts by applying layout elements of extracted sub-cells to a boundary condition of an IC to be designed, and the virtually placed layouts may be input to a machine learning model to compare result values, thereby selecting a template having a minimized area and WL.

FIG. 12 is a flowchart illustrating an example of a method of fabricating an IC.

Referring to FIG. 12, a standard cell library D10 may include information on standard cells, for example, function information, characteristic information, layout information, and the like. The standard cell library D10 may include data DC defining layouts of the standard cells. In some implementations, the standard cell library D10 may include data defining a digital logic device.

Operations S10 and S20 are an operation of designing an IC, in which layout data D30 may be generated from register transfer level (RTL) data D11.

In operation S10, a logic synthesis operation of generating netlist data D20 from the RTL data D11 may be performed.

For example, a semiconductor design tool (e.g., a logic synthesis module) may generate the netlist data D20 including a bitstream or a netlist by performing logic synthesis on the RTL data D11 with reference to the standard cell library D10, the RTL data D11 being created by a hardware description language (HDL), such as a very high-speed integrated circuit (VHSIC) HDL (VHDL) or Verilog. The standard cell library D10 may include the data DC defining the structures of standard cells which perform the same function and have different layouts, and the standard cells may be included in an IC by referring to such information in a logic synthesis process. In some implementations, operation S10 may be applied to a process of designing a digital logic circuit.

In some implementations, when an analog logic circuit or a mixed-signal circuit other than a digital logic circuit is designed, operation S10 may be omitted, and circuit data represented by a combination of transistors may be transferred. In some implementations, such circuit data represented by a combination of transistors may be included in the netlist data D20. The netlist data D20 may include both a digital logic circuit, as shown in FIG. 7A, and an analog logic circuit.

In operation S20, a P&R operation of generating layout data D30 from the netlist data D20 may be performed. The layout data D30 may have, for example, a format, such as generic or geometric data structure information interchange (GDSII), and include geometric information of the standard cells and interconnections. In an implementation, operation S20 may include operations S100 to S600 of FIG. 1. According to the present disclosure, the netlist data D20 may correspond to netlist data described in the present disclosure, and the layout data D30 may indicate data of which P&R has been completed based on a finally selected template. According to the present disclosure, layout elements corresponding to a plurality of sub-cells may be virtually placed based on template-related data D21, and the virtually placed layout elements may be input to a machine learning model to evaluate a virtually placed layout. As a result, a template having an optimal condition may be selected, and a layout based on the selected template may be generated. Accordingly, the layout data D30 may be generated.

In some implementations, the template-related data D21 may include the template database D1, the learning database D2, and the machine learning model M1 shown in FIG. 3.

In addition, the semiconductor design tool may perform a routing operation that is an operation of generating interconnections, in operation S20. The routing operation may be an operation of placing wiring layers and vias required to appropriately connect placed standard cells according to design rules for an IC. The interconnection may electrically connect an output pin to an input pin of a standard cell and include, for example, at least one via and a conductive pattern formed on at least one metal layer. Patterns formed on metal layers at different levels may be electrically connected to each other via a via including a conductive material. Herein, a metal layer may include a metal as a conductive material.

In operation S30, optical proximity correction (OPC) may be performed. OPC may indicate a work for forming a desired-shaped pattern by correcting a distortion phenomenon, such as refraction, caused by the characteristics of light in photolithography included in a semiconductor process for fabricating an IC, and a pattern on a mask may be determined by applying OPC to the layout data D30. In an implementation, a layout of an IC may be limitedly modified in operation S30, and the limited modification of the IC in operation S30 is post-processing for optimizing a structure of the IC and may be referred to as design polishing.

In operation S40, an operation of manufacturing a mask may be performed. For example, patterns on a mask may be defined to form patterns on a plurality of layers by applying OPC to the layout data D30, and at least one mask (or a photomask) for forming the respective patterns of the plurality of layers may be manufactured.

In operation S50, an operation of fabricating an IC may be performed. For example, the IC may be fabricated by using the at least one mask, manufactured in operation S40, to pattern a plurality of layers. Operation S50 may include operations S51, S53, and S55 and include a deposition process, an etching process, an ionization process, a cleaning process, and the like. In addition, operation S50 may include a packaging process of mounting a semiconductor device on a printed circuit board (PCB) and sealing the same by using a sealing material, and include a test process of testing the semiconductor device or package.

In operation S51, a front-end-of-line (FEOL) process may be performed. The FEOL process may indicate a process of forming individual devices, e.g., transistors, capacitors, and resistors, on a substrate in a process of fabricating an IC. For example, the FEOL process may include planarizing and cleaning a wafer, forming a trench, forming a well, forming a gate line, forming source and drain regions, and the like.

In operation S53, a middle-of-line (MOL) process may be performed. The MOL process may indicate a process of forming a connection member for connecting, in a standard cell, the individual elements generated through the FEOL process. For example, the MOL process may include forming an active contact in an active region, forming a gate contact on the gate line, forming a via on the active contact and the gate line, and the like.

In operation S55, a back-end-of-line (BEOL) process may be performed. The BEOL process may indicate a process of interconnecting individual devices, e.g., transistors, capacitors, and resistors, in a process of fabricating an IC. For example, the BEOL process may include silicidation of gate, source, and drain regions, adding a dielectric, performing planarization, forming a hole, forming metal layers, forming a via between the metal layers, forming a passivation layer, and the like. Thereafter, the IC may be packaged in a semiconductor package and used as a component of various applications.

FIG. 13 is a block diagram illustrating an example of a computing system 100 for designing an IC.

Referring to FIG. 13, the computing system (hereinafter, referred to as the IC design system) 100 for designing an IC may include a processor 110, a memory 130, an input/output device 150, a storage device 170, and a bus 190.

The IC design system 100 may perform a layout placement operation including operations S100 to S600 of FIG. 1. In an implementation, the IC design system 100 may be implemented by an integrated device and accordingly, may be referred to as an IC design device. The IC design system 100 may be provided as a dedicated device to design an IC of a semiconductor device or may be a computer configured to drive various simulation tools or design tools. The IC design system 100 may be a stationary computing system, such as a desktop computer, a workstation, or a server, or a portable computing system, such as a laptop computer.

The processor 110 may be configured to execute instructions for performing at least one of various operations for designing an IC. For example, the processor 110 may include a core, such as a micro-processor, an application processor (AP), a digital signal processor (DSP), or a graphics processing unit (GPU), capable of executing an arbitrary instruction set (e.g., Intel Architecture-32 (IA-32), 64-bit extended IA-32, x86-64, PowerPC, Sparc, million instructions per second (MIPS), advanced RISC (reduced instruction set computer) machine (ARM), IA-64, or the like). The processor 110 may communicate with the memory 130, the input/output device 150, and the storage device 170 via the bus 190. The processor 110 may execute an IC design operation by driving a synthesis module 131, a P&R module 132, and a design rule check (DRC) module 133 loaded on the memory 130.

The memory 130 may store the synthesis module 131, the P&R module 132, and the DRC module 133. The synthesis module 131, the P&R module 132, and the DRC module 133 may be loaded from the storage device 170 to the memory 130. The synthesis module 131 may be a program including a plurality of instructions for performing a logic synthesis operation.

The P&R module 132 may be a program including a plurality of instructions for performing a layout placement operation according to operations S100 to S600 of FIG. 1.

The DRC module 133 may determine whether there exists a design rule error. The DRC module 133 may be a program including a plurality of instructions for performing a DRC operation. If there exists a design rule error, the P&R module 132 may adjust a layout of placed cells. If there does not exist a design rule error, a layout design of an IC may be completed.

Although not shown in FIG. 13, a program including a plurality of instructions for performing the method of generating a learning model with reference to FIG. 2 may be included in the memory 130.

The memory 130 may be a volatile memory, such as static random access memory (SRAM) or dynamic random access memory (DRAM), or a non-volatile memory, such as phase change random access memory (PRAM), resistive random access memory (ReRAM), nano floating gate memory (NFGM), polymer random access memory (PoRAM), magnetic random access memory (MRAM), ferroelectric random access memory (FRAM), or flash memory.

The input/output device 150 may control a user input and output from user interface devices. For example, the input/output device 150 may include input devices, such as a keyboard, a mouse, and a touch pad, and receive input data or the like defining an IC. For example, the input/output device 150 may include output devices, such as a display and a speaker, and display a displacement result, a routing result, layout data, a DRC result, and the like.

The storage device 170 may store programs, such as the synthesis module 131, the P&R module 132, and the DRC module 133, and before a program is executed by the processor 110, the program or at least a portion of the program may be loaded from the storage device 170 to the memory 130. The storage device 170 may store data to be processed by the processor 110 or data processed by the processor 110. For example, the storage device 170 may store data (e.g., a standard cell library 171, netlist data, and the like) to be processed by programs, such as the synthesis module 131, the P&R module 132, and the DRC module 133, and data (e.g., DRC result data, layout data, and the like) generated by the programs. In some implementations, the storage device 170 may store the template-related data D21 of FIG. 12.

For example, the storage device 170 may include a non-volatile memory, such as electrically erasable programmable read-only memory (EEPROM), flash memory, PRAM, RRAM, MRAM, or FRAM, or a storage medium, such as a memory card (a multi-media card (MMC), an embedded MMC (eMMC), a secure digital (SD) card, a microSD card, or the like), a solid state drive (SSD), a hard disk drive (HDD), a magnetic tape, an optical disc, or a magnetic disc. In addition, the storage device 170 may be detachable from the IC design system 100.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A method of placing a layout, the method comprising:
extracting a plurality of sub-cells based on netlist data;
generating a first plurality of layout elements corresponding to the plurality of sub-cells;
performing virtual placement of the first plurality of layout elements to obtain at least one virtually placed layout, the first plurality of layout elements corresponding to a plurality of layout elements that at least one template contains;
selecting, based on evaluating the at least one virtually placed layout, a first template from the at least one template; and
placing and routing the first plurality of layout elements based on the first template.

2. The method of claim 1, wherein the netlist data comprises information characterizing a plurality of transistors.

3. The method of claim 1, wherein each template of the at least one template comprises placement structure information of a second plurality of layout elements included in a product layout.

4. The method of claim 3, wherein the second plurality of layout elements match the first plurality of layout elements.

5. The method of claim 3, wherein performing virtual placement of the first plurality of layout elements is based on a relative position relationship of the second plurality of layout elements included in the product layout.

6. The method of claim 5, wherein the relative position relationship is based on a meta grid scheme, and the virtual placement of the first plurality of layout elements is performed according to the relative position relationship of the second plurality of layout elements.

7. The method of claim 5, wherein the relative position relationship is based on a vertical constraint graph, and the virtual placement of the first plurality of layout elements is performed according to the relative position relationship of the second plurality of layout elements.

8. The method of claim 5, wherein the relative position relationship is based on a horizontal constraint graph, and the virtual placement of the first plurality of layout elements is performed according to the relative position relationship of the second plurality of layout elements.

9. The method of claim 1, wherein the first plurality of layout elements are subject to a boundary condition to be generated in an integrated circuit during virtual placement of the first plurality of layout elements.

10. The method of claim 1, wherein selecting the template comprises inputting the at least one virtually placed layout to a machine learning model trained on the at least one template.

11. The method of claim 10, comprising evaluating the at least one virtually placed layout based on at least one of a wire length and/or an area value that is an output of the machine learning model.

12. The method of claim 10, wherein the machine learning model is based on a convolutional neural network (CNN) model.

13. The method of claim 12, wherein learning data for training the machine learning model comprises placement layout information of a plurality of sub-cells included in each template of the at least one template, constraint area information, pin information, connection structure information, and coordinate information.

14. A method of designing an integrated circuit, the method comprising a place and routing operation of generating layout data from netlist data, wherein the place and routing operation comprises:
extracting a plurality of sub-cells from the netlist data, the netlist data including information characterizing a plurality of transistors;
generating a first plurality of layout elements corresponding to the plurality of sub-cells, respectively;
virtually placing the first plurality of layout elements based on template-related data to obtain a plurality of virtually placed layouts, wherein the template-related data comprises a second plurality of layout elements corresponding to the plurality of sub-cells, respectively;
selecting, based on evaluating the plurality of virtually placed layouts, a template of which a wire length or area is minimized; and
placing and routing the first plurality of layout elements based on the template.

15. The method of claim 14, wherein the first plurality of layout elements have different shapes and sizes corresponding to different transistor structures of the plurality of sub-cells.

16. The method of claim 14, wherein the template-related data comprises:
a template database including layout placement structure information of a plurality of layout elements included in a product layout;
a learning database storing learning data for learning a plurality of templates; and
a machine learning model trained on the learning data.

17. The method of claim 14, wherein virtually placing the first plurality of layout elements comprises virtually placing the first plurality of layout elements based on a relative position relationship of the second plurality of layout elements included in the template-related data.

18. The method of claim 14, wherein virtually placing the first plurality of layout elements comprises performing virtual placement such that the first plurality of layout elements correspond to a boundary condition to be generated in an integrated circuit.

19. The method of claim 16, wherein selecting the template comprises:
inputting the plurality of virtually placed layouts to the machine learning model generated by machine-learning the learning data stored in the learning database; and
evaluating the plurality of virtually placed layouts based on at least one of a wire length and/or an area value that is an output of the machine learning model.

20. A system for designing an integrated circuit, the system comprising:
a processor; and
a memory connected to the processor and storing instructions for layout placement to design the integrated circuit, wherein the processor is configured, when the instructions are executed, to:
extract a plurality of sub-cells based on netlist data;
generate a first plurality of layout elements corresponding to the plurality of sub-cells;
perform virtual placement of the first plurality of layout elements to obtain at least one virtually placed layout, the first plurality of layout elements corresponding to a plurality of layout elements that at least one template contains;
select, based on evaluating the at least one virtually placed layout, an template; and
place and route the first plurality of layout elements based on the template.
